(19) United States
(12) Patent Application Publication
(10) Pub. No.: US 2008/0096043 A1
(43) Pub. Date: Apr. 24, 2008

(54) Process and Equipment For Obtaining Metal Or Metal Matrix Components With A Varying Chemical Composition Along The Height Of The Component And Components Thus Obtained

(75) Inventor: Filipe Samuel Correia Pereira Da Silva, Braga (PT)

Correspondence Address: MARSH, FISCHMANN & BREYFOGLE LLP, 3151 SOUTH VAUGHN WAY, SUITE 411, AURORA, CO, 80014, US

(73) Assignee: UNIVERSIDADE DO MINHO, Braga (PT)

(21) Appl. No.: 11/572,650

(22) PCT Filed: Jul. 27, 2004
(86) PCT No.: PCT/PT04/00020

§ 371 Date: Apr. 17, 2007

(51) Int. Cl. B32B 5/00; B22D 25/06; B22D 27/04; F02F 3/00; C30B 13/20; B22D 46/00

(52) U.S. Cl. 428/610; 117/74; 123/193.6; 164/154.1; 164/493

(57) ABSTRACT

The present invention relates to a method of production of functionally graded materials based on an incremental melting and solidification process. Its operation principle can be described as follows: the materials (metal elements, alloys or ceramics) are melt by the induction heating in the mould, and the continual granules, powders or wire, or even liquid materials, of another metal alloys are fed to the mould. The heating zone is limited to a small part of the mould. The incremental melting and solidification process proceeds from the bottom to the top of the mould by changing the relative position between the mould and the heating apparatus. Usage of this method ensures the obtainment of components with no particular alloy composition, but with a gradual changing of the chemical composition along the casting. As a result the component will have a continuous variation of the chemical composition along the component resulting in different physical, tribologycal, and mechanical properties along the component.

### DOMAIN OF THE ART TO WHICH IT REFERS

This invention refers to a process of incremental melting and solidification, in order to produce materials with a gradient of properties.

### PRIOR ART

A method, similar to this one has been used in turbine blades in order to achieve single crystal components, and oriented grain components. Another process using two different alloys has been proposed, where the first alloy is poured to the crucible, and the bottom part of this alloy is solidified. When only the top part of the alloy is liquid, the other alloy is poured into the crucible, and the whole component is then solidified. This allows the obtainment of a two part components, with different chemical compositions. Another similar process has also been used to achieve a functionally graded material, through the insertion of silicon carbide particles or other reinforcement materials as the material is being solidified from bottom to top of the component.

The incremental melting and solidification process has found application in few component, particularly those who need to have high corrosion resistance at high temperatures. This is the case of single crystal (SC) and directional solidification (DS) titanium turbine blades. In these processes, the apparatus generally comprises a vacuum chamber inside which there are disposed a mould heating zone, a baffle system, a water-cooled chill plate usually made of copper, an induction furnace, and a thermocouple system that automatically controls and maintains the temperature in a cooling zone and in a heating zone within the furnace. A molten alloy is poured in a vacuum into a ceramic mould, which is sitting on a water-cooled copper chill plate. The chill plate is mounted on a ram, which is withdrawn as solidification progresses through the casting. The solidification front is the key to the Directional Solidification and to the Single Crystal casting. In this process, the alloy is completely poured into the ceramic mould, in a liquid phase. The heating zone moves upwards keeping the upper part of the alloy liquid, while the bottom part solidifies. The bottom part of the alloy is solidified with the help of the water-cooled copper chill plate. These features are disclosed in U.S. Pat. Nos. 3,680,625, 4,804,311, and 4,412,577.

Another similar processes include in the cooling zone, a cooling bath with a material that melts easily to serve the role of the cooling medium. The apparatus are disclosed in U.S. Pat. No. 5,129,7531, and the liquid bath is disclosed is U.S. Pat. Nos. 3,763,926, and 3,915,761.

Another similar process is disclosed on Patent U.S. Pat. No. 3,847,203. In this process a first molten alloy is poured into a mould and progressively cooled to produce a vertical columnar growth. A second molten alloy is then poured in while the surface of the first alloy is still liquid. The progressive cooling is then continued. In this process, a suitable ceramic mould has an overflow tube formed in the wall of the mould so that any excess of the first alloy will run off. With this method it can be obtained components formed with different parts with different alloys, with controlled columnar crystal growth.

The closest prior art to the present invention is an apparatus that is presented at a ICCM-13 Conference paper, by Wang, Jia, and Yin. This process uses the incremental melting and solidification process and has been used to produce composite functionally graded materials. In this process, the alloy is fed to the mould gradually. The heating is zone moves upwards keeping the upper part of the alloy liquid, and the bottom part of the alloy solid. As the heating zone moves upwards the raw material is fed, in a solid state, to the liquid zone of the alloy. During the process the raw material that is fed to the mould has the same chemical composition. The reinforcement is fed to the mould in a way that the final component has different volume fraction of reinforcement along the component.

Patent U.S. Pat. No. 5,791,395 relates to a one shot multicolour metal casting method, and Patent U.S. Pat. No. 5,952,113 relates to multi-coloured cast jewellery. In both patents a casting process obtains articles of multicoloured gold jewellery. The process consists on casting in one piece by introducing into a casting cavity in a mould, via separate gates from separate sprues and at essentially at the same time, separate melts of gold differently alloyed to produce gold of different colours. Although the piece may have different colours they will be separate by a transition region between each colour.

### SUMMARY OF THE INVENTION

The technical aim of this invention is to produce castings with a different chemical composition along the component. The chemical composition varies continuously along the component. To this different chemical composition correspond different physical, tribologycal, and mechanical properties along the casting.

There is no particular interface between two specific alloys, or parts of the component with a particular chemical composition, as mentioned in a previous Patent (U.S. Pat. No. 3,847,203).

The resulting casting will be a specific metallic alloy, with a gradual chemical composition (no specific chemical composition), and not a metal alloy with a particular chemical composition and grain orientation (as mentioned on Patents U.S. Pat. Nos. 3,680,625, 4,804,311, 4,412,577, 3,763,926, and 3,915,761), or even a specific metal alloy with reinforcements differently distributed along the component as mentioned on the ICCM-13 Conference paper, by Wang, Jia, and Yin.

This invention is new in relation to the documents of techniques already cited because: on patents U.S. Pat. No. 3,680,625, U.S. Pat. No. 4,804,311, U.S. Pat. No. 4,412,577, U.S. Pat. No. 3,763,926, and U.S. Pat. No. 3,915,761, the resulting component will be on a metal alloy with a particular chemical composition and grain orientation along the whole component; on patent U.S. Pat. No. 3,847,203 the component is composed of two distinct parts with specific chemical compositions and an interface between the two specific alloys; and on the ICCM-13 Conference paper, by Wang, Jia, and Yin, the component is in a specific metal alloy with reinforcements differently distributed along the component.

Patents U.S. Pat. No. 5,791,395 U.S. Pat. No. 5,952,113 relates to a casting process where the obtained components have specific chemical compositions in different parts of the component and transition regions in between. The process is also very different in these last patents.

To achieve said aim the inventive apparatus comprises a vacuum chamber inside which there is disposed an induction melting furnace with a ceramic mould, a drive assembly for mould transportation, a water cooling system, and different alloy feeders.

### BRIEF DESCRIPTION OF DRAWINGS

The following description makes use, for a better understanding, of the drawings attached, which are presented as merely exemplificative in which:

FIG. 1 shows schematically the apparatus used in the process that gave origin this invention;

FIG. 2 shows the same equipment in another schematic view; and

FIGS. 3 to 7 represent, also in a schematic way, the operation sequence, by which is obtained a component, according to this invention.

### DETAILED DESCRIPTION OF AN OPERATING SEQUENCE

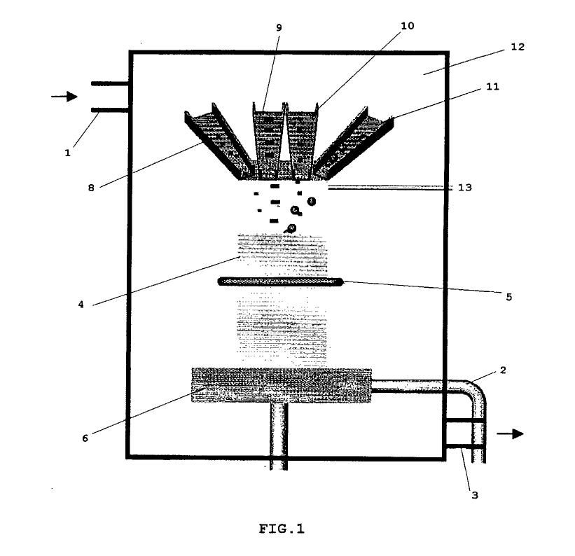

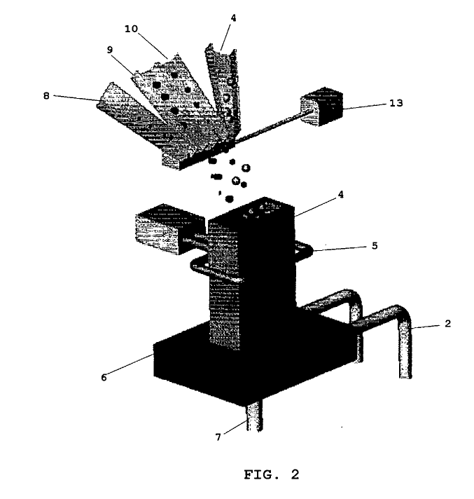

As can be seen in FIGS. 1 and 2 the equipment is composed by:

1—Protective environment circuit;

2—Chill cooling circuit;

3—Vacuum circuit;

4—Mould with temperature control at different points using thermocouples;

5—Induction heating spire (device);

6—Cool chill copper device;

7—Rod;

8—Automatically controlled feeder;

9—Automatically controlled feeder;

10—Automatically controlled feeder;

11—Automatically controlled feeder;

12—Vacuum chamber

13—Feeding controller (PLC or Computer);

The Operating Sequence may be Described as Follows

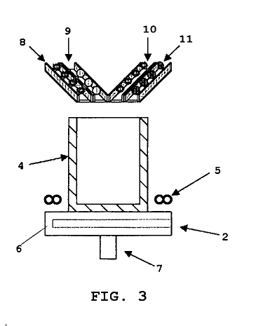

The different raw materials are placed at the feeders (8-11) as shown of FIG. 3.

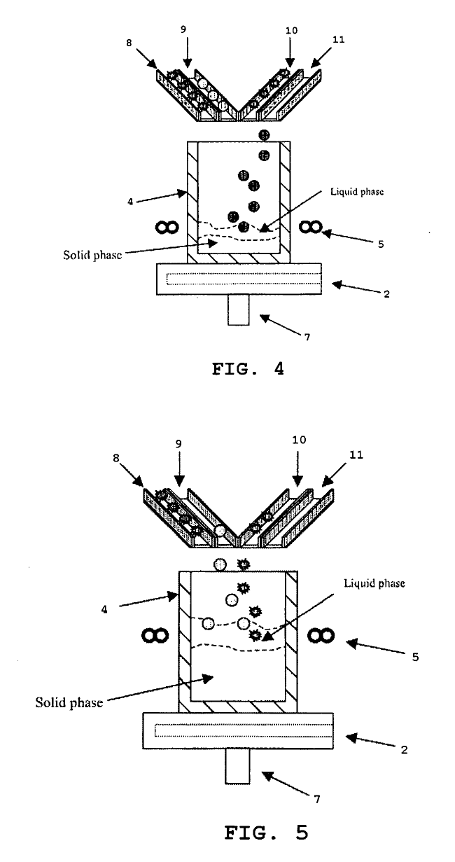

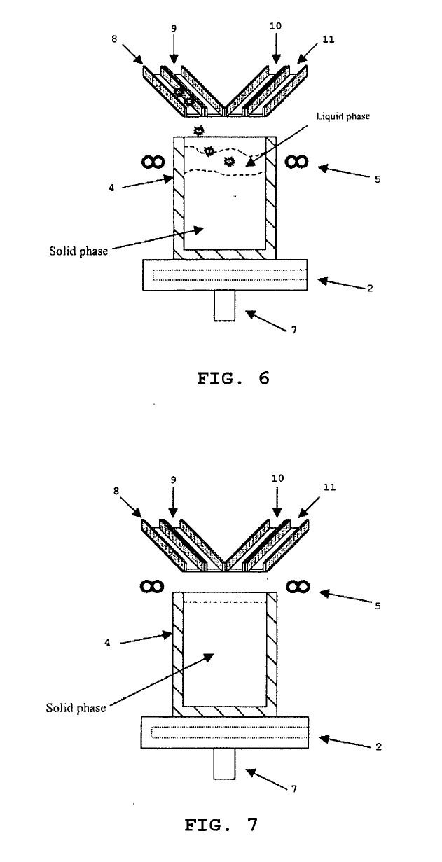

After the heating device 5 is turned and the cooling device 2 of cool chill copper device 6, feeder 11 feeds a material, while the induction coil 5 starts his vertical upwards movement. The bath surface is still liquid while the alloy at the bottom of the mould is already solidified. This stage is represented in FIG. 4.

As the heating device moves upward, see FIG. 5, another feeder 10 (or feeders) start feeding the mould 4 with another elements, alloys or materials (these elements, alloys or materials may be in the solid state as powder, granules or wire, or in the liquid state). The bath surface is still liquid while the solidified part at the bottom of the mould keeps growing.

As the heating device 5 moves upwards another feeder 9 starts feeding the mould 4 with another elements, alloys or materials. The bath surface is still liquid while the solidified alloy at the bottom of the mould keeps growing.

Finally, when all the material has been fed to mould 4, see FIG. 5, the induction coil keeps moving upwards, till all the material inside the mould is at the solid state. A component, with functional gradient properties, is obtained.

The Apparatus Performs as Follows:

The mould (4) is disposed on the cool chill copper device (6) that is mounted on the movable rod (7). The cool chill device and the movable rod comprise the drive assembly. The mould is placed in the cool chill device and its relative position in relation to the heating device (5) is controlled so that the heating device is located at the bottom of the mould.

The raw materials are placed at the feeders 8-11. The raw materials can be either alloying elements or base alloys with different chemical compositions or even ceramic materials. They can be in the form of powder, granules or wire, or being at the liquid state. The vacuum chamber 12 is evacuated 3 to 10⁻³ Pa. The inert gas 1 is introduced into the chamber. The heating device 5 is turned on and the mould is preheated. Raw materials start then to be fed to the mould in a way to obtain a certain amount of material with a known chemical composition. The water of the cooling device 2 is turned on and the temperature of the cool chill copper device 6 is controlled. This temperature is controlled with a thermocouple. The heating device 5 is then heated till the temperature of the alloy, already inside the mould, reaches 100-150° C. higher than its ‘liquidus’ temperature. Temperature of the bath is controlled with the use of thermocouples (not represented) placed at the side of the mould or with an infrared thermocouple placed above the top of the liquid bath.

When the material inside the mould is liquid, the heating device 5 starts is movement upwards with a required speed rate (the movable rod 4 is fixed). (It can be the opposite, e.g. the movable rod 4 starts a downwards movement with a required speed rate while the heating device 5 is fixed). At a certain point solidification of the molten alloy starts at the bottom of the mould 4, because the bottom of the mould 4 is cooled by the copper chill 6 and is not directly heated by induction coil 5 any more. The bath surface inside the mould 4 is still liquid.

Raw materials, with different but controlled chemical compositions and in different proportions keep feeding mould 4 in a controlled way. The induction device starts going upwards with a certain speed rate.

The process proceeds in a way so that the bath surface remains liquid while the solid part keeps growing. This solid part already has a chemical composition gradient along its height.

The feeders are automatically controlled (with a PLC—programmable logic computer or by a computer and a specific software) 13 in a way that the chemical composition of the liquid part of the component is approximately known. The same controller controls the feeding rate of the materials as well as the heating device (induction coil) movement and the heating power.

Three variables, that are dependent on each other, are controlled for each desired component:

The heating temperature of the induction coil. Shall vary along the process according to the ‘liquidus’ temperature of the material chemical composition of the liquid portion (at the bath surface);

The feeding rate of the raw materials of each feeder. Must be so that the chemical composition of each part of the obtained component is known;

The speed rate of the moving heating device (or rod). Shall vary along the process according to the energy necessary to melt the material;

Once the process is completed, e.g., the top of the mould 4 is full and solidified, the heating device is switched off. When the temperature of the mould reaches 200-300° C., the installation in then decompressed, the protective gas is removed, and the mould with the solidified casting alloy is extracted from the installation. Then, the process is repeated with another casting (and eventually another mould).

With this process components with a gradual chemical composition can be obtained. If different mechanical properties in different parts of the component are required, the component may have different chemical compositions in order to achieve the mechanical properties goal. The frontiers or bonds of the process lie on metallurgical properties such as solubility limits or ‘liquidus’ temperature of the compositions.

Thus, the resulting casting alloy will not have a specific chemical composition. The component may be a Mg based alloy on one side of the component, a Al based alloy in the middle part, and on the other side may be a Ti based alloy. Or the component may be an Al based alloy, for example, but with a gradual shifting of the alloying elements such as Silicon or Magnesium.

The process mentioned in the present invention allows the obtainment of high quality castings, with low porosity, low shrinkage, and in different sizes, allowing new trends in design.

It will consecutively be indicated some process examples for some components without any limitative character

### EXAMPLE 1

### Manufacture of an Engine Piston with a Changing in Base Materials

The mould 4 is disposed on the cool chill copper device 6 that is mounted on the movable rod 7 and its relative position in relation to the heating device 5 is controlled so that the heating device is located at the bottom of the mould.

The raw materials (in powder, granules or wire, or in the liquid state) are placed at the feeders 8-11. Feeder 11 may have a magnesium based alloy (91% Mg; 8.5 Al; 0.5% Zn), feeder 10 may have an Aluminium based alloy (85% Al; 12% Si; 3% Cu), feeder 9 may have a titanium based alloy (90% Ti; 6% Al; 4% V), and feeder 8 may have pure aluminium (Al);

The vacuum chamber 12 is evacuated 3 to a pressure of about 10⁻³ Pa and the inert gas 1 is introduced into the chamber. The heating device 5 is turned on and the mould 4 is preheated;

Raw material from feeder 11 (91% Mg; 8.5 Al; 0.5% Zn) starts feeding the mould and the water of the cooling device 2 of the chill copper device 6 is turned on and the temperature of the chill copper device 6 is controlled with a thermocouple;

The heating power of the heating device is raised till the temperature of the alloy reaches 100-150° C. higher than its ‘liquidus’ temperature. Temperature of the bath is controlled with the use of thermocouples placed at the side of the mould or with an infrared thermocouple placed at the top of the mould 4;

When the material inside the mould 4 is liquid, the induction coil 5 starts moving upwards with a required speed rate (the mould 4 is fixed). At a certain point solidification of the molten alloy starts at the bottom of the mould 4, while the bath surface is still liquid;

The induction coil keeps its upwards movement with a certain speed rate while raw materials from feeder 10 (85% Al; 12% Si; 3% Cu) and feeder 8 (Al) start to feed the mould 4 with a controlled feeding rate in order that the base material changes from a magnesium based alloy to an aluminium based alloy. Feeder 11 (91% Mg; 8.5 Al; 0.5% Zn) stops feeding the mould 4. The solidified level of the component inside the mould 4 increases and the upward movement of the heating device are in a way that the amount of liquid alloy at the bath surface keeps about the same;

As the moving induction coil goes more upwards raw materials from feeder 8 (Al) keeps feeding the mould 4 while feeder 9 (90% Ti; 6% Al; 4% V) starts feeding the mould 4 both with a controlled rate. Feeder 10 (85% Al; 12% Si; 3% Cu) stop. At this point the base material changes from an aluminium based alloy to a titanium based alloy. The heating power of the heating device may have to increase because the ‘liquidus’ temperature of the new base alloy is higher, and also the speed rate of the moving heating device may decrease, to allow a complete melt of the new alloy. The solidified amount of the component keeps increasing while the liquid quantity of the alloy keeps about the same;

As the moving induction coil goes more upwards raw materials from feeder 9 (90% Ti; 6% Al; 4% V) and feeder 8 (Al) keep feeding the mould 4 with a certain speed rate. The base material of the liquid part of the casting is now a titanium-based alloy and only the level of aluminium is changing. The solidified amount of the component keeps increasing while the liquid quantity of the alloy keeps about the same;

As the induction coil goes more upwards raw materials from feeder 8 (Al) stop and only feeder 9 (90% Ti; 6% Al; 4%V) keeps feeding the mould with a certain speed rate. The base material is now a titanium-based alloy similar to the one of feeder 9 (90% Ti; 6% Al; 4% V). The solidified amount of the component keeps increasing while the liquid quantity of the alloy keeps about the same;

As the induction coil goes more upwards raw materials from feeder 9 (90% Ti; 6% Al; 4% V) stop. The base material has now almost the same composition of the titanium based alloy of feeder 9 (90% Ti; 6% Al; 4% V). The solidified amount of the component keeps increasing till the whole casting is solidified;

Once the whole casting inside the mould 4 is solidified, the heating device is switched off, till the temperature of the mould 4 reaches 200-300° C.;

The installation in then decompressed, the protective gas removed, and the mould 4 with the solidified casting alloy is extracted from the installation. Then, the process is repeated with another casting (and eventually another mould).

### EXAMPLE 2

### Manufacture of an Engine Piston with the Same Base Material (Aluminium) and with a Changing in the Alloying Elements

The mould 4 is disposed on the cool chill copper device 6 that is mounted on the movable rod 7. Its relative position in relation to the induction coil 5 is controlled so that the heating device is located at the bottom of the mould 4.

The raw materials (in powder, granules or wire, or in the liquid state) are placed at the feeders (9-11). Feeder 11 may have an Aluminium based alloy (85% Al; 12% Si; 3% Cu); feeder 10 may have an aluminium-based alloy (77% Al; 30% Si; 1% Fe) rich in silicon; and feeder 9 may have pure aluminium (Al);

The vacuum chamber 12 is evacuated by the evacuating system 3 a pressure of about to 10⁻³ Pa and the inert gas 1 is introduced into the chamber 12. The heating device 5 is turned on and the mould 4 is preheated.

Raw material from feeder 11 (85% Al; 12% Si; 3% Cu) starts to feed the mould 4 and the water of the cooling device 2 is turned on and the temperature of the cool chill copper device 6 is controlled with a thermocouple. The power of the heating device 5 is then increased till the temperature of the alloy reaches 100-150° C. higher than its ‘liquidus’ temperature. Temperature of the bath is controlled with the use of thermocouples placed at the side of the mould or by an infrared thermocouple placed at the top of mould 4;

When the material inside the mould is liquid, the induction coil starts its movement upwards with a required speed rate (mould 4 is fixed). At a certain point solidification of the molten alloy starts at the bottom of the mould 4, while the bath surface is still liquid;

The induction coil keeps its movement upwards with a certain speed rate while raw materials from feeder 10 (77% Al; 30% Si; 1% Fe) and feeder 9 (Al) start to feed the mould 4 with a controlled rate in order that the base material at the bath surface (that is still liquid) changes smoothly from an aluminium with a low content in Silicon to an aluminium based alloy with a high content in Silicon. The solidified level of the component, inside the mould 4, keeps growing while the amount of liquid alloy keeps about the same

As the induction coil goes more upwards raw materials from feeder 10 (77% Al; 30% Si; 1% Fe) and feeder 9 (Al) keep feeding the mould in a way that the base material at the bath surface (that is still liquid) keeps increasing the level of silicon. Feeder 11 (85% Al; 12% Si; 3% Cu) stops feeding the mould 4. The heating power of the heating device 5 may have to increase because the ‘liquidus’ temperature of the new base alloy (with an higher content in Silicon) is higher. The speed rate of the heating device may decrease, to allow a complete melt of the new alloy. The solidified level of the component, inside the mould 4, keeps growing while the amount of liquid alloy keeps about the same;

As the induction coil goes more upwards raw materials from feeder 9 (Al) stop while raw material from feeder 10 (77% Al; 30% Si; 1% Fe) keep feeding the mould 4 with a certain speed rate. The base material of the liquid bath is now an aluminium-based alloy with a high content in Silicon, similar to the one of feeder 10. The solidified level of the component, inside the mould 4, keeps growing while the amount of liquid alloy keeps about the same;

As the induction coil goes more upwards raw materials from feeder 10 (77% Al; 30% Si; 1% Fe) stops. The base material of the liquid bath has now the same chemical composition of feeder 10 (77% Al; 22% Si; 1% Fe). The solidified level of the component, inside the mould 4, keeps growing while the amount of liquid alloy keeps about the same;

Once the whole casting inside the mould 4 is solidified, the heating device 5 is switched off, till the average temperature of the mould reaches about 200-300° C.;

The installation in then decompressed, the protective gas removed, and the mould 4 with the solidified casting alloy is extracted from the installation. Then, the process is repeated with another casting (and eventually another mould).

### EXAMPLE 3

### Manufacture of a Jewellery Component with the Same Base Material (Gold) and a Changing in the Alloying Elements

The mould 4 is disposed on the cool chill copper device 6 that is mounted on the movable rod 7. Its relative position in relation to the heating device 5 is controlled so that the heating device is located at the bottom of the mould 4.

The raw materials (in powder, granules or wire, or in the liquid state) are placed at the feeders (8-11). Feeder 11 may have a Gold based alloy (75% Au; 4.5% Ag; 20.5% Cu). This alloy has a red colour; feeder 10 may have silver (Ag); feeder 9 may have Copper (Cu), and feeder 8 may have pure gold (Au);

The vacuum chamber 12 is evacuated by the evacuating system 3 a pressure of about to 10⁻³ Pa and the inert gas 1 is introduced into the chamber 12. The heating device 5 is turned on and the mould 4 is preheated.

Raw material from feeder 11 (75% Au; 4.5% Ag; 20.5% Cu) starts feeding the mould 4 and the water of the cooling device 2 of the cool chill copper device 6 is turned on and the temperature of the chill copper device 6 is controlled with a thermocouple.

The power of the heating device is then increased till the temperature of the alloy reaches 100-150° C. higher than its liquidus temperature. Temperature of the bath is controlled with the use of thermocouples placed at the side of the mould 4 or an infrared thermocouple placed at the top of mould 4;

When the material inside the mould 4 is liquid, the heating device (induction coil) starts to go upwards with a required speed rate (mould 4 is fixed). At a certain point solidification of the molten alloy starts at the bottom of the mould 4, while the bath surface is still liquid;

The induction coil 5 keeps going upwards with a certain speed rate while raw materials from feeder 10 (Ag), feeder 9 (Cu) and feeder 8 (Au) start to feed the mould 4, each feeder with a own controlled rate in order that the base material of the liquid part of the casting changes from a gold based alloy rich in copper to a gold alloy with the same content of copper and silver that corresponds to a yellow colour. The solidified level of the component, inside the mould 4, keeps growing while the amount of liquid alloy keeps about the same;

As the induction coil 5 goes more upwards raw materials from feeder 11 (75% Au; 4.5% Ag; 20.5% Cu) stop. Feeder 10 (Ag), feeder 9 (Cu), and feeder 8 (Au) keep feeding the mould each feeder with a own controlled speed rate in order to achieve a certain chemical composition. The solidified level of the component, inside the mould 4, keeps growing while the amount of liquid alloy keeps about the same;

As the induction coil 5 goes more upwards raw materials from feeder 10 (Cu) stop. Feeder 9 (Ag) and feeder 8 (Au) keep feeding the mould 4. The liquid bath becomes rich in Ag and poor in Cu. The liquid part of the bath becomes a gold alloy rich in Silver that corresponds to a greenish colour. The solidified level of the component, inside the mould 4, keeps growing while the amount of liquid alloy keeps about the same;

As the induction coil 5 goes more upwards raw materials from feeder 9 (Ag) and feeder 8 (Au) stop. The solidified level of the component, inside the mould 4, keeps growing in a way that all the casting become solidified;

Once the casting inside mould 4 is solidified, the heating device 5 is switched off, till the average temperature of the mould reaches about 200-300° C.;

The installation in then decompressed, the protective gas removed, and the mould 4 with the solidified casting alloy is extracted from the installation. Then, the process is repeated with another casting (and eventually another mould).

Examples of Components that can be Obtained by Using the Process Described in this Invention are:

Engine pistons where its skirt may be in a magnesium based alloy with an initial certain chemical composition and the head of the piston may be in a titanium based alloy with a certain composition, with a gradual changing of the chemical composition between the bottom part (the skirt) and the top part (the head), of the piston; The middle part of the component (piston) may be an aluminium based alloy. Or a piston where the skirt (bottom part) is composed by an aluminium based alloy with a low percentage of Silicon, and as we go through the top of the piston, the volume fraction of silicon increases, reaching the head of the piston (top of the piston) with an alloy that corresponds to an aluminium based alloy with an high content of silicon. (this is an example of a mechanical and tribologycal functionally graded component)

Jewellery components (rings, brooches, pendants, charms, etc.), where one side on the component is composed by a gold based alloy with a certain chemical composition (ex: 75% Au, 4.5% Cu; 20.5% Ag) that corresponds to a red gold alloy, and as we go through the other side on the component, the chemical composition gradually changes (keeping the gold content (Au) and increasing the content of Silver (Ag), and decreasing the content of Copper (Cu) giving rise to a changing in colour along the component, and as it's reached the other side of the component, the chemical composition may be (ex. 75% Au, 25% Ag) that corresponds to a greenish colour. This is an example of a physical functionally graded material where it's obtained a unique natural effect of smooth transition of one colour to another and another in a jewellery piece reflecting high aesthetical criteria of jewellery accessories manufacturing at the world market.

This process has several application domains such as the automotive field, aeronautic, jewellery, etc.

1. A process to manufacture metallic components or metal matrix components with a chemical composition variation along the length of the component, as those using an incremental melting and solidification process, in order to produce functionally gradient materials, characterized by, during the component casting, raw materials, fed by the feeders, are continually fed to the mould placed on a cooling device in order to promote solidification of the material at the bottom of the mould, that is heated by an induction coil that moves upwards from the bottom to the top of the mould, heating a limited area of the mould, and keeping the casting surface liquid, and controlling during the whole process, the interdependent variables:
The heating temperature of the induction coil that must vary according to the ‘liquidus’ temperature of the chemical composition of the liquid part of the bath (at the top of the casting);
The feeding rate of the raw materials of each feeder that must be done according to the desired chemical composition for each part of the component;
The speed rate of the moving induction coil that may vary during the whole process according to the energy necessary to melt the material;

2. A process to obtain metallic or metal matrix composites, according to claim 1, characterized by every stage of the process may be carried out inside a vacuum chamber where, after under pressurized at about 10⁻³ Pa an inert protective gas may be introduced

3. A process to obtain metallic or metal matrix composites, according to claim 1, characterized by, before starting the feeding of raw materials by the feeders, the mould is pre-heated and, after starting the feeding with the first feeder, the chill cool device, above which the mould is placed, be cooled allowing the control of the temperature of the chill cool device and of the bottom of the mould.

4. A process to obtain metallic or metal matrix composites, according to claim 1, characterized by different materials, alloy elements, alloys or ceramics, are placed on the feeders so that they are sequentially fed to the mould, materials that may be in the solid state as granules, powders or wire, or even in the liquid state.

5. A process to obtain metallic or metal matrix composites, according to claim 1, characterized by the temperature of the chill cool device and of the mould is controlled by thermocouples and the temperature of the bath is controlled by thermocouples placed at the wall of the mould and/or a thermocouple placed at the top of the mould.

6. A process to obtain metallic or metal matrix composites, according to claim 1, characterized by the induction coil promotes the melt of the material that is inside the mould, e.g. about 100-150° C. above its ‘liquidus’ temperature.

7. Equipment for the production of cast components, with a gradual shift of chemical composition along its length, according to the process of claim 1, and characterized by being composed by: vacuum chamber with a vacuum system; system to work with a protective environment; induction heating device composed by an induction coil; a ceramic or metallic mould placed on a chill device and on a rod; a cooling system to cool the bottom of the mould; a feeding system to feed materials in the solid state (as powder, granules or wire) or in the liquid state; a programmable system that allows the automatic and simultaneous control of the feeders of the different materials, of the heating system movement, and of the induction heating power.

8. Cast components according to claim 1, characterized by present a chemical composition variation along its length, and a consequent variation of their mechanical, physical and/or tribologycal properties along its height.

9. Cast multicoloured gold based, platinum based, or silver based jewellery components, according to claim 8, with a gradual shift among different colours, along the height of the piece.

10. Cast engine pistons, according to claim 8, characterized by having a gradual chemical composition shifting along its length, and subsequent mechanical, physical and tribologycal properties shift along the height of the component.
